(19) United States
(12) Patent Application Publication
(10) Pub. No.: US 2013/0075779 A1
(43) Pub. Date: Mar. 28, 2013

(54) LIGHT EMITTING DIODE WITH MULTIPLE TRANSPARENT CONDUCTIVE LAYERS AND METHOD FOR MANUFACTURING THE SAME

(71) Applicants: CHIA-HUI SHEN, Hsinchu (TW); TZU-CHIEN HUNG, Hsinchu (TW)

(72) Inventors: CHIA-HUI SHEN, Hsinchu (TW); TZU-CHIEN HUNG, Hsinchu (TW)

(73) Assignee: ADVANCED OPTOELECTRONIC TECHNOLOGY, INC., Hsinchu Hsien (TW)

(21) Appl. No.: 13/528,842

(22) Filed: Jun. 21, 2012

(30) Foreign Application Priority Data
Sep. 26, 2011 (CN) 201110287875.0

(51) Int. Cl. H01L 33/42

(52) U.S. Cl. 257/99; 257/E33.064

(57) ABSTRACT

A light emitting diode includes a first-type semiconductor layer, an active layer, a second-type semiconductor layer and a transparent, electrically conductive layer formed in sequence. The transparent, electrically conductive layer includes a first transparent, electrically conductive layer on the second-type semiconductor layer and a second transparent, electrically conductive layer on the first transparent, electrically conductive layer. Both the first and second transparent, electrically conductive layers are made of indium tin oxide, while the first transparent, electrically conductive layer has a smaller thickness. During formation of the transparent, electrically conductive layer, a mass flow of introduced oxygen gas to the first transparent conductive layer is lower than that to the second transparent conductive layer.

### BACKGROUND

1. Technical Field

The disclosure relates to light emitting diodes, and particularly to a light emitting diode with multiple transparent conductive layers and a method for manufacturing the light emitting diode.

2. Description of the Related Art

A conventional light emitting diode (LED) includes a substrate, a light emitting structure having a N-type semiconductor layer, an active layer and a P-type semiconductor layer formed on the substrate in sequence, and two electrodes (i.e., N-type and P-type electrodes) respectively connected to the N-type and P-type semiconductor layers. To achieve a homogenous current distribution in the semiconductor layers while do not lower the light extraction efficiency, a transparent conductive layer which is made of an indium tin oxide (ITO) layer is formed between the P-type electrode and the N-type semiconductor layer.

Generally, the ITO layer is required to have a low contact resistance, high light transparency and low resistivity. However, in fact, the thinner the ITO layer is, the higher the light transparency but the poorer the electrical property, i.e. higher contact resistance and higher resistivity. Furthermore, during the formation of the ITO layer, if it is formed at an oxygen-rich environment, the ITO layer will have a poor electrical property; on the other hand if it is formed at an oxygen-poor environment, the ITO layer will have a poor transparency.

Therefore, it is desirable to provide a light emitting diode and a method for manufacturing a light emitting diode with both good electrical property and relatively high light transparency.

### BRIEF DESCRIPTION OF THE DRAWINGS

Many aspects of the disclosure can be better understood with reference to the drawings. The components in the drawings are not necessarily drawn to scale, the emphasis instead being placed upon clearly illustrating the principles of the present light emitting diode and a method for manufacturing the light emitting diode. Moreover, in the drawings, like reference numerals designate corresponding parts throughout the views.

FIG. 1 is a cross-sectional view of a light emitting diode in accordance with an exemplary embodiment of the present disclosure.

FIG. 2 is a flow chart of a method showing steps of a method for manufacturing the light emitting diode of FIG. 1.

### DETAILED DESCRIPTION

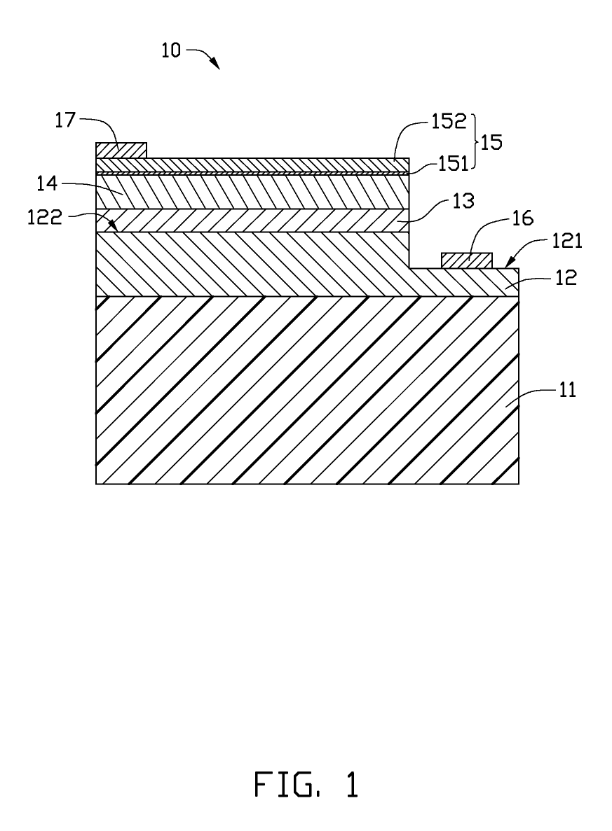

Referring to FIG. 1, a light emitting diode 10 in accordance with an exemplary embodiment is provided. The light emitting diode 10 includes a substrate 11, a first-type semiconductor layer 12, an active layer 13, a second-type semiconductor layer 14, a transparent conductive layer 15, a first electrode 16, and a second electrode 17 having an opposite polarity with respect to the first electrode 16. The transparent conductive layer 15 is transparent to light and conductive to electricity. When a bias is applied to the first and second electrodes 16, 17, electron holes and electrons flow from the first-type semiconductor layer 12 and the second-type semiconductor layer 14 to recombine at the active layer 13, whereby light is emitted from the active layer 13.

The substrate 11 is dielectric. The substrate 11 can be sapphire (α-Al₂O₃) substrate, silicon carbide (SiC) substrate, etc.

The first-type semiconductor layer 12, the active layer 13, the second-type semiconductor layer 14, and the transparent conductive layer 15 are formed on the substrate 11 in sequence from bottom to top. In other words, the first-type semiconductor layer 12 is formed on the substrate 11 directly. The active layer 13 is sandwiched between the first-type semiconductor layer 12 and the second-type semiconductor layer 14. The first-type semiconductor layer 12, the active layer 13 and the second-type semiconductor layer 14 can be made of III-V or II-VI compound semiconductors. The first-type semiconductor layer 12 and the second-type semiconductor layer 14 are doped with different materials. In this embodiment, the first-type semiconductor layer 12 is N-type doped, and the second-type semiconductor layer 14 is P-type doped. In alternative embodiment, the first-type semiconductor layer 12 can be P-type doped, and the second-type semiconductor layer 14 can be N-type doped.

The first-type semiconductor layer 12 is formed on the substrate 11 and has an exposed first area 121 and a covered second area 122 farthest away from the substrate 11. The first area 121 is uncovered by the active layer 13 and the second-type semiconductor layer 14. The second area 122 is covered by the active layer 13 and the second-type semiconductor layer 14. Alternatively, a buffer layer (not shown) made of GaN or AlN can be grown on the substrate 11 before the first-type semiconductor layer 12 formed on the substrate 11 to improve the easiness of growth of the first-type semiconductor layer 12 on the substrate 11. The first area 121 is substantially strip-shaped and positioned at a lateral end of the first-type semiconductor 12. In addition, the shape and position of the first area 121 can be changed. For example, the first area 121 can be an annular area around the second area 122.

The active layer 13 can be a single quantum well (SQW) structure or a multiple quantum well (MQW) structure.

The transparent conductive layer 15 is formed on the second-semiconductor layer 14. The transparent conductive layer 15 includes a first transparent conductive layer 151 and a second transparent conductive layer 152. The first and second transparent conductive layers 151, 152 are both made of ITO and accordingly are both ITO layers. The first transparent conductive layer 151 is directly grown on the second-type semiconductor layer 14, and then the second transparent conductive layer 152 is grown on the first transparent conductive layer 151. A thickness of the first transparent conductive layer 151 is smaller than that of the second transparent conductive layer 152. Parameters for forming the first transparent conductive layer 151 and the second transparent conductive layer 152 are different. When the first transparent conductive layer 151 is being formed, a mass flow of introduced oxygen gas is less than 7 standard-state cubic centimeters per minute, and the thickness of the first transparent conductive layer 151 is less than 500 angstroms (Å). The indium tin oxides film, i.e. the first transparent conductive layer 151, will have an excellent electrical property when the oxygen content (concentration) thereof is relatively low. As such, the first transparent conductive layer 151 is formed in ohmic contact with the second-type semiconductor layer 14 to drop a working voltage of the light emitting diode 10. A light permeability of the first transparent conductive layer 151 can be improved because the thickness of the first transparent conductive layer 151 is less than 500 Å. When the second transparent conductive layer 152 is being formed, the mass flow of introduced oxygen gas is greater than 7 standard-state cubic centimeters per minute, and the thickness of the first transparent conductive layer 151 is more than 1000 Å and less than 5000 Å. The indium tin oxides film, i.e. the second transparent conductive layer 152, will have an excellent light transmission when the oxygen content (concentration) is relatively high. As such, the relatively large thickness of the second-type semiconductor 14 will not affect the light transmission thereof. The second transparent conductive layer 152 will not increase the working voltage of the light emitting diode 10 because of the excellent ohmic contact between the first transparent conductive layer 151 and the second transparent conductive layer 152. In addition, even that a transverse current distribution of the first transparent conductor layer 151 is poor because of the relatively small thickness thereof, the relatively thick second first transparent conductor layer 152 grown on the first transparent conductor layer 151 do have an excellent traverse current distribution which can efficiently improve a uniformity of integral transverse current distribution of the whole transparent conductive layer 15. Thus, a current transmission in a vertical direction and the current distribution in a transverse direction are both improved by the smaller thickness of the first transparent conductor layer 151 and the relatively large thickness of the second transparent conductor layer 152 in combination.

In an alternative embodiment, the light emitting diode 10 can be a vertical structure. Furthermore, the substrate 11 can be omitted.

The first electrode 16 is formed on the first area 121 of the first-type semiconductor layer 12. The second electrode 17 is formed on the second transparent conductive layer 152. The first electrode 16 has a same polarity as the first-type semiconductor layer 12, and the second electrode 17 has a same polarity as the second-type semiconductor layer 14.

The present disclosure provides the first transparent conductive layer 151 and the second transparent conductive layer 152 successively formed on the semiconductor layer 14. The first transparent conductive layer 151 is formed with a relatively low oxygen content to make the first transparent conductive layer 151 in ohmic contact with the second-type semiconductor layer 14, and a relatively small thickness to reduce the negative effect to the light transmission caused by the relatively low oxygen content. The relatively thick second transparent conductive layer 152 is formed with a high oxygen content to improve the current distribution in the transverse direction without affecting the light transmission. As such, the current transmission in a vertical direction and the current distribution in a transverse direction are both improved.

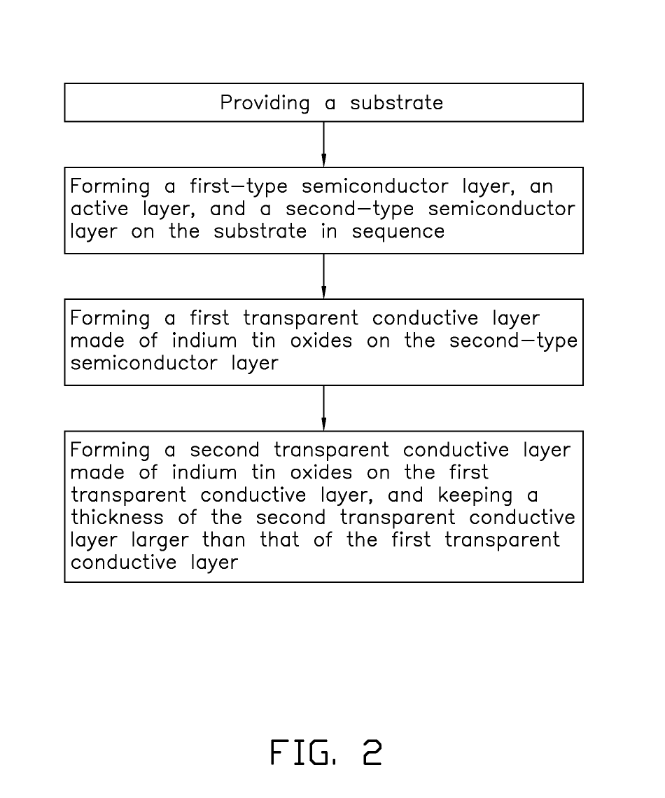

FIG. 2 shows a flow chart of a method for manufacturing the light emitting diode 10. The method for manufacturing the light emitting diode 10 includes the following steps.

Firstly, the substrate 11 is provided.

Secondly, the first-type semiconductor layer 12, the active layer 13, and the second-type semiconductor layer 14 are successively formed on the substrate 11.

Thirdly, the first transparent conductive layer 151 made of indium tin oxide is formed on the second-type semiconductor layer 14.

Fourthly, the second transparent conductive layer 152 made of indium tin oxide is formed on the first transparent conductive layer 151, and the thickness of the second transparent conductive layer 152 is larger than that of the first transparent conductive layer 151.

In the manufacturing process, the exposed first area 121 of the first-type semiconductor layer 12 is formed by inductively coupled plasma dry etching. The first transparent conductive layer 151 is formed by introducing oxygen gas with a mass flow less than 7 standard-state cubic centimeters per minute. The thickness of the first transparent conductive layer 151 is less than 500 Å. The second transparent conductive layer 152 is formed by introducing oxygen gas greater than 7 standard-state cubic centimeters per minute. The thickness of the second transparent conductive layer 152 is more than 1000 Å and less than 5000 Å. In this embodiment, the first-type semiconductor layer 12, the active layer 13, the second-type semiconductor layer 14, and the transparent conductive layer 15 can be successively formed on a sapphire substrate or a GaN substrate through a Metal Organic Chemical Vapor Deposition (MOCVD) equipment.

A step of forming the first electrode 16 on the first area 121 of the first-type semiconductor 12 and a step of forming the second electrode 17 on the second transparent conductive layer 152 can be further provided after the step of forming the transparent conductive layer 15.

It is to be understood that the above-described embodiments are intended to illustrate rather than limit the disclosure. Variations may be made to the embodiments without departing from the spirit of the disclosure as claimed. The above-described embodiments illustrate the scope of the disclosure but do not restrict the scope of the disclosure.

What is claimed is:

1. A light emitting diode, comprising:
a first-type semiconductor layer;
an active layer formed on the first-type semiconductor layer;
a second-type semiconductor layer formed on the active layer; and
a transparent, electrically conductive layer formed on the second-type semiconductor layer, the transparent, electrically conductive layer comprising a first transparent, electrically conductive layer on the second-type semiconductor layer and a second transparent, electrically conductive layer on the first transparent, electrically conductive layer;
wherein the first transparent, electrically conductive layer and the second transparent, electrically conductive layer are both made of indium tin oxide, a concentration of oxygen in the first transparent, electrically conductive layer is lower than that in the second transparent, electrically conductive layer, and a thickness of the first transparent, electrically conductive layer is smaller than that of the second transparent, electrically conductive layer.

2. The light emitting diode of claim 1, wherein the thickness of the first transparent, electrically conductive layer is less than 500 Å.

3. The light emitting diode of claim 2, wherein the thickness of the second transparent, electrically conductive layer is more than 1000 Å and less than 5000 Å.

4. The light emitting diode of claim 1 further comprising a first electrode and a second electrode.

5. The light emitting diode of claim 4, wherein the first-type semiconductor layer comprises a first area and a second area, the first area being exposed outside, the second area being covered by the active layer.

6. The light emitting diode of claim 5, wherein the first electrode is formed on the first area of the first-type semiconductor layer, and the second electrode is formed on the second transparent, electrically conductive layer.

7. The light emitting diode of claim 1 further comprising a substrate, the first-type semiconductor, the active layer, the second-type semiconductor, and the transparent, electrically conductive layer being formed on the substrate in sequence.

8. The light emitting diode of claim 1, wherein the first-type semiconductor layer is an N-type semiconductor layer and the second-type semiconductor layer is a P-type semiconductor layer.

9. The light emitting diode of claim 1, wherein the transparent, electrically conductive layer is in ohmic contact with the second-type semiconductor layer.

10. The light emitting diode of claim 1, wherein the active layer is a single quantum well structure or a multiple quantum well structure.

11. A method for manufacturing a light emitting diode comprising steps:
providing a substrate;
forming a first-type semiconductor layer, an active layer, and a second-type semiconductor layer on the substrate in sequence;
forming a first transparent, electrically conductive layer made of indium tin oxide on the second-type semiconductor layer; and
forming a second transparent, electrically conductive layer made of indium tin oxide on the first transparent, electrically conductive layer, a thickness of the second transparent, electrically conductive layer being larger than that of the first transparent, electrically conductive layer.

12. The method for manufacturing a light emitting diode of claim 11, wherein the first transparent, electrically conductive layer is formed by introducing oxygen gas with a mass flow less than 7 standard-state cubic centimeters per minute.

13. The method for manufacturing a light emitting diode of claim 12, wherein a thickness of the first transparent, electrically conductive layer is less than 500 Å.

14. The method for manufacturing a light emitting diode of claim 11, wherein the second transparent, electrically conductive layer is formed by introducing oxygen gas with a mass flow more than 7 standard-state cubic centimeters per minute.

15. The method for manufacturing a light emitting diode of claim 14, wherein a thickness of the second transparent, electrically conductive layer is more than 1000 Å and less than 5000 Å.

16. The method for manufacturing a light emitting diode of claim 11, wherein the first-type semiconductor layer comprises a first area and a second area, the first area being exposed outside, and the second area being covered by the active layer.

17. The method for manufacturing a light emitting diode of claim 11, wherein the first-type semiconductor layer is an N-type semiconductor layer and the second-type semiconductor layer is a P-type semiconductor layer.

18. The method for manufacturing a light emitting diode of claim 16, further comprising a step of forming a first electrode on the first area of the first-type semiconductor and a step of forming a second electrode on the second transparent, electrically conductive layer after the step of forming the second transparent, electrically conductive layer.
